(19) United States
(12) Patent Application Publication
(10) Pub. No.: US 2016/0299262 A1
(43) Pub. Date: Oct. 13, 2016

(54) APPARATUS AND PROCESS FOR ANNEALING OF ANTI-FINGERPRINT COATINGS

(71) Applicant: OERLIKON ADVANCED TECHNOLOGIES AG, Balzers (LI)

(72) Inventors: Heiko Plagwitz, Konstanz (DE); Stephan Voser, Sevelen (CH)

(21) Appl. No.: 15/036,441

(22) PCT Filed: Nov. 13, 2014
(86) PCT No.: PCT/CH2014/000162

§ 371 Date: May 13, 2016

Related U.S. Application Data
(60) Provisional application No. 61/904,159, filed on Nov. 14, 2013.

(51) Int. Cl. G02B 1/18; B05D 3/00; B05D 1/18; C23C 14/22; B05D 1/02

(52) U.S. Cl. CPC G02B 1/18; C23C 14/22; B05D 1/02; B05D 1/18; B05D 3/007

(57) ABSTRACT

The present invention addresses an in-situ annealing station for treating a substrate in an atmosphere of controlled water vapour pressure at a defined temperature. Such a station can be integrated as a process chamber into a multi chamber processing tool in which an anti-fingerprint coating process is being performed. The substrate is always under vacuum conditions until the annealing process has finished. Experimental data show that a significant reduction of the subsequent ex-situ curing duration can be achieved compared to Prior Art by introducing this in-situ treatment in water vapour immediately after the anti-fingerprint coating step.

The invention further addresses a deposition process for a substrate to be annealed by exposing it to water-vapour under sub atmospheric pressure at a temperature of ca. 130° C. for about 5 s.

This invention relates to a process and according vacuum chamber design for the in-situ annealing of anti-fingerprint coatings directly after deposition of such coatings. Typically, such anti-fingerprint coatings are applied to the touch-sensitive cover glasses of electronic devices (smartphones, tablet PCs).

A chemical binding reaction between such anti-fingerprint coating and glass surface has to be accomplished to ensure good adhesion. This binding reaction typically requires water.

The content of EP 2 409 317, EP 2 409 339 and WO 2013/057228 is incorporated by reference herein in its entirety, especially with a view on the basic deposition process of anti-fingerprint coatings and functionality of an inline vacuum deposition system.

### BACKGROUND OF THE INVENTION

Anti-fingerprint coatings provide an easy-to-clean, non-sticking surface finish for touch-sensitive surfaces such as smartphone or tablet PC cover glasses. The surface becomes oleophobic and hydrophobic which allows easy removal of particles and grease and also allows for a comfortable feeling when actually using such a touch panel device. Typically, chemical solutions of alkoxy silane molecules are used for this application, because the silane group of these molecules provides hydrophobic and oleophobic functionality whereas the alkoxy group forms a strong covalent bond to glass.

Several coating techniques are used in the industry: Dip coating, spray coating, or physical vapour coating. WO 2013/057228 describes equipment for physical vapour deposition from liquid precursors (alkoxy silane molecules dissolved in a solvent).

All of these coating techniques require a subsequent curing step, because the chemical bonding reaction between the alkoxy group and the glass surface has to be initiated. This reaction consumes water; therefore the curing is typically performed by placing the substrates in a hot, humid environment for several hours. Alternatively, curing can also be accomplished by exposing such coated substrates to humidity from the ambient air for several days.

The chemical precursor materials as well as instructions for processing and curing are commercially available from manufacturers like Daikin or Dow Corning (see e.g. Dow Corning 2634 product information, Daikin Optool DSX product information). In this disclosure the term anti-smudge or anti-fingerprint material is being used interchangeably for materials of this kind.

As mentioned above the proposed curing processes to date typically take several hours and can therefore only be applied reasonably in batch processes where a large number of substrates are treated simultaneously. In industrial scale this requires voluminous conditioning cabinets with respective load, heat, cool down and unload processes.

### DISADVANTAGES OF PRIOR ART METHODS

In summary, the established ex-situ curing methods have two main disadvantages:

1. They typically require controlled humidity (>50%) and temperature (>50° C.) simultaneously. Therefore, process control is quite sophisticated.

2. Typical curing processes take several hours. Therefore, curing has to be separated from the coating process (done in another tool), which increases the overall costs. High throughput in industrial scale necessitates large tools, which increases investment costs.

The goal of this application is therefore a significant reduction or elimination of the curing time period by introducing an in-situ treatment in water vapour atmosphere immediately after coating without breaking vacuum.

### BRIEF DESCRIPTION OF THE FIGURES

FIG. 1a: Photograph of an annealing station according to the invention

FIG. 1b: An inventive annealing apparatus in a schematic overview

FIG. 2: Vacuum deposition tool with multiple chambers for substrate cleaning (PC1), anti-fingerprint (AF) deposition (PC4), in-situ annealing (PC 5).

FIG. 3: Durability of differently cured anti-fingerprint coating on glass, measured by the steel wool abrasion test

### SUMMARY OF THE INVENTION

This present invention addresses an in-situ annealing station construed to adjust and control a water vapour pressure and a defined process temperature; said station can be integrated as a process chamber into a multi chamber processing tool in which an anti-fingerprint coating process is being performed. The substrate is always under vacuum conditions until the annealing process has finished. Experimental data show that a significant reduction of the ex-situ curing duration can be achieved by introducing this in-situ treatment in water vapour immediately after the coating step. This can even eliminate the need for slow batch-type curing processes and allows for a fast in-line coating and curing sequence with the substrates being continuously processed. The invention therefore has the potential to lower production costs.

A radiative heating station has been used to facilitate an in-situ post-deposition annealing process with adjustable water vapour pressure. A suitable multi-chamber tool has been described e.g. in EP 2 409 317 and EP 2 409 339 and such a basic coating process has been described in WO 2013/057228.

The annealing station is technically based on a radiative heater station as it is known in the art. It is widely known to use quartz lamps positioned in a close spatial relationship to a substrate to be heated up. In the present invention said annealing station has been additionally equipped with an adjustable water supply to allow for a dosing of water into the heater station, such that the heating step can be performed in the presence of water vapour. In consequence, a rapid thermal anneal with adjustable water vapour pressure can be performed. Placed in the same tool as the DLD (Direct Liquid Deposition) station described in WO 2013/057228 this allows the deposition and in-situ water vapour treatment in one and the same machine in one and the same process cycle.

### DETAILED DESCRIPTION OF THE INVENTION

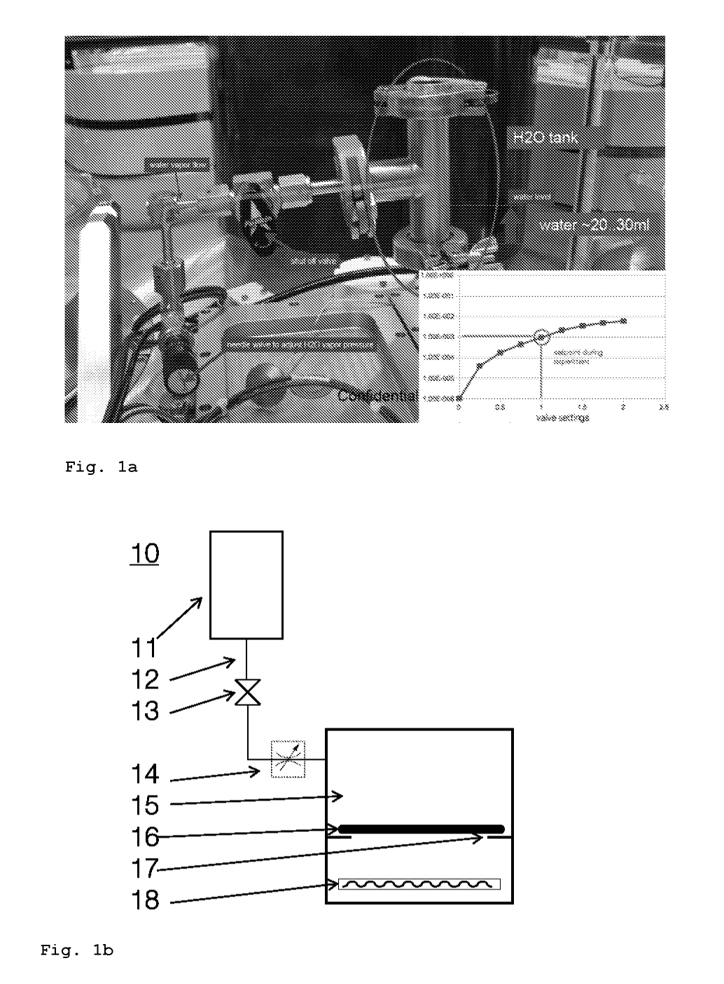

FIG. 1a shows a photograph of the annealing station. A T-piece has been used as an H₂O tank or water reservoir. A conduit connects the water reservoir and the annealing station.

When the connection between water reservoir and vacuum chamber is being opened, the water in the reservoir will boil due to the reduced pressure. A needle valve between said water reservoir and the vacuum (annealing) chamber allows thus adjusting the water vapour pressure. The substrate (inside the chamber, not shown) is heated by an array of halogen lamps. FIG. 1b shows the inventive annealing apparatus 10 in a more schematic overview. The water reservoir or supply tank 11 is connected via tube or piping 12 to the annealing chamber 15. Said chamber includes substrate holding means 17 which can, in operation, support a substrate 16. Heating means such as a quartz heater 18 are arranged in chamber 15, not necessarily on the bottom of chamber 15. The water can be blocked from flowing into chamber 15 by means of a blocking valve 13—this is helpful, in case reservoir 10 needs to be refilled, but not mandatory for the inventive principle. A needle valve or other kind of control valve 14 allows for defining the amount of water passing valve 14. Since chamber 15 is kept under sub atmospheric pressure during operation, the water will vaporize and fill the chamber if valves 13 and 14 allow for an inflow of water. Valves 13, 14 can be operated manually or by means of actuators, which opens the possibility to control those valves via respective electronics and software in a process control environment.

Evacuating means such as pumps as well as measuring units (pressure and temperature control means) have been omitted in this scheme. It goes without saying that the resulting water vapour pressure in chamber 15 will be the result of water vapour supply (controlled via valve 14), the pumping power installed and the volume of chamber 15.

In an inventive process a substrate (preferable one or at least one, if e.g. a substrate carrier is being used) is being placed in an annealing chamber 15 by means of a robot or other transport means. The chamber will be separated from ambient during the annealing step. Via valve 14 a defined amount of water is being dosed into chamber 15 to develop water vapour to take effect on the coating which had been deposited in a previous vacuum deposition step. The dosing can be done in one step, i.e. a defined portion of water for the curing to be inserted once per annealing step, in a discontinuous way (pulsed) or in a continuous dosing. Depending on the volume of the annealing chamber and the pump power the necessary water volume to be dosed will vary, therefore the respective parameter named below is the resulting vapour pressure (target pressure) in the chamber.

Heater 18 acts in parallel to the dosing on the substrate and is elevating its temperature to the desired and defined level. Pressure and temperature control means allow for dynamically controlling this process; alternatively fixed settings for heater and water dosing can be used which may be derived from earlier experiments. After a predetermined treatment time in the annealing chamber, the water inflow may be stopped, the residuals pumped away and the substrate can be removed from the chamber. Depending on the level of dosage it is also possible to simply allow said defined dose of water passing constantly into chamber 15, if the pump capacity allows for it and if cross-contamination is no issue in the respective system.

It has been found to be especially advantageously that after said earlier deposition step the annealing step takes place immediately without breaking vacuum. This way any contamination from ambient air which may have negative effect on the molecular reactions described above, can be avoided.

The following parameters have found to be useful:

Annealing time: 5 s

Annealing temperature: 130° C.

Resulting water vapour pressure in annealing chamber: 1×10⁻³ to 1×10⁻² mbar (hPa)

Advantageously, the annealing step is integrated as a process step in an inline substrate treatment tool. This allows integrating the annealing into the sequence of process steps which is necessary to deposit the anti-fingerprint layer.

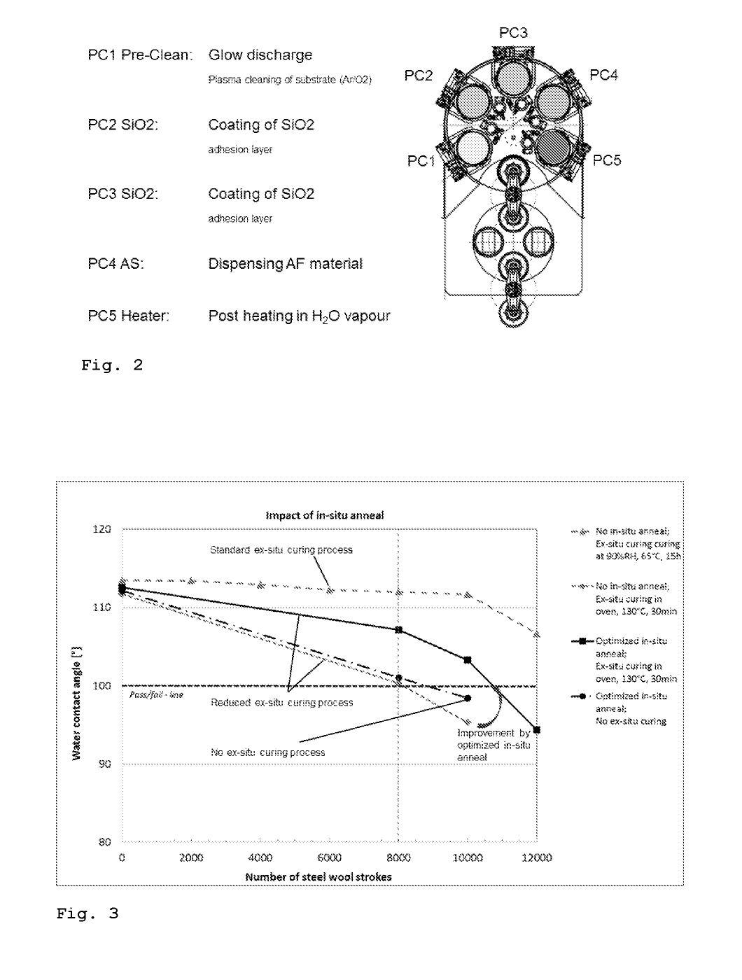

FIG. 2 shows a typical in-situ processing sequence and an accordingly equipped inline substrate treatment tool. FIG. 2 shows a system with multiple chambers for substrate cleaning (PC1), anti-fingerprint (AF) deposition (PC4), in-situ annealing (PC 5). The sequence of chambers corresponds to the sequence in which substrates are processed. The throughput is approximately one substrate in 5 s.

In this case the process stations are arranged in a circle and a respective handler provides for a sequential access of the process stations PC1-PC4. The substrate surface is pretreated and coated in analogy to patent application WO2013/057228A1 in chamber PC1-PC4. Chamber 5 is the inventive annealing station. There is no vacuum break between coating and annealing.

In such kind of deposition tool the substrates are being fed from a waiting position via a Load Lock into a vacuum section (the upper part with process stations). They sequentially have access to PC1 to PC5 before being brought back to atmosphere. In more detail such a system has been described in EP 2 409 317 and EP 2 409 339. In PC2 and PC3 an adhesion layer is being deposited. In order to match the cycle time of about 5 s, two stations are being used so the overall treatment time for the SiO₂ coating can be distributed on two stations. This way, the limitations of a sequential deposition tool, where the “slowest” process station limits the tact time, can be remedied.

A typical process in industrial environment uses, after a regular cleaning of the substrate with a detergent the following process steps in a vacuum environment:
a) a surface conditioning by glow discharge (plasma cleaning)
b) deposition of 5-15 nm of SiO₂ (can be accomplished in 1 process stations or split up into 2 or more)
c) deposition of about 20 nm of anti-smudge or anti-fingerprint material
d) annealing process according to the invention

A standard steel wool abrasion test was performed to assess the durability of anti-fingerprint coatings after curing. In this test, a steel-wool pad (grade “0000”) of 1 cm² size is being charged with 1 kg and a series of strokes with this pad being performed over the coated and annealed surface at a speed of about 5 cm/s.

FIG. 3 shows the durability of differently cured anti-fingerprint coatings on glass, measured by the steel wool abrasion test. Goal is a water contact angle of >100° after at least 8000 strokes. Black curves indicate samples that were in-situ annealed in water vapour, grey curves indicate samples that were processed without in-situ anneal. Utilizing the in-situ annealing method allows to reduce the ex-situ curing duration significantly from 15 hours in controlled humidity to 30 minutes in a simple oven, and still achieve good performance.

The wear resistance of the coating is determined by the water contact angle test, in which a drop of water is placed on the surface of the substrate and the contact angle between the water droplet and the surface is measured. The water contact angle measured vs. certain numbers of strokes of the steel wool pad is shown in FIG. 3. The larger the water contact angle, the better the coating and the less wear the glass exhibits.

The results of various curing processes in FIG. 3 are:
1. No in-situ annealing but standard (Prior Art) ex-situ curing (15 hours at 65° C., 90% relative humidity): These samples have the best possible performance, as shown by the grey triangles in FIG. 3 (uppermost curve)
2. No in-situ annealing but reduced ex-situ curing (30 min at 130° C., low relative humidity): This process was developed to achieve a water contact angle (WCA) of >100° after at least 8000 strokes. The boundary conditions were (a) minimum ex-situ curing duration and (b) no extra humidity during curing. The results of these samples are indicated by the grey diamonds (lowest curve).
3. In-situ annealing in water vapour+Reduced ex-situ curing:
   The inventive curing process improves the performance and durability of the coating considerably, as indicated by the black squares in FIG. 3 (second curve from above). This shows that the in-situ curing process allows reducing the requirements of ex-situ curing tremendously from 15 hours in controlled humidity to 30 min in low humidity, and still achieves a high performance of the anti-fingerprint coating. This can lead to significant cost reductions.
4. In-situ annealing in water vapour+No ex-situ curing: This allows similar performance as with treatment no. 2, which means that 30 min of process time can be saved. This again can lead to significant cost reductions in production. This curve is marked with round dots (=third from above).

Comparing samples no. 2 and 4 of FIG. 3 gives a nice example how the process duration is reduced by the present invention: 5 seconds of in-situ annealing will save 30 minutes of ex-situ curing, but result in the same, or slightly better, film quality.

Furthermore, comparison of samples no. 1 and 3 shows that the short in-situ anneal in water vapour drastically reduces the duration of, and also eliminates the need for high humidity in, the subsequent ex-situ curing process when aiming at very high film quality.

These experimental data show that the hardware and corresponding process flow according to the invention has the potential to significantly reduce process time in the production of anti-fingerprint coated devices. Reduced process duration translates into reduced production costs, which is beneficial for our customers.

In summary, a processing station for simultaneously heating a substrate and charging it with water vapour comprises at least an evacuable enclosure or chamber with an adjustable and controllable supply for water into said chamber and a heating means allowing for elevating the temperature of a substrate arranged in said chamber and means for evacuating said chamber to a predefined pressure level. Said processing chamber may include a substrate support, temperature and pressure control means, handling means for arranging, loading and unloading a substrate. Said adjustable and controllable supply for water into said chamber comprises control means for dosing water, such as valves, throttle valves, preset valve, needle valves or alike which may be actuated manually or via a drive.

Consequently, a deposition process for an anti-fingerprint coating on glass, comprises a process sequence including (a) deposition of the anti-fingerprint coating and (b) in-situ curing with water vapour without vacuum break in between. A curing process for a surface of a substrate coated with an anti-fingerprint coating of the kind described herein, will include the features
Exposing this surface to an atmosphere of water vapour between 1×10³ to 1×10⁻² mbar (hPa), preferably 1×10⁻³ mbar (hPa) at an elevated temperature around 130° C. +/−10%, preferably +/−5%.

Said curing process as described above will preferably last for a few seconds, preferably 5 s, and/or is adjusted to the tact time of an inline substrate treatment system performing said curing process and other treatment steps.

What is claimed is:

1. An annealing apparatus (10) for simultaneously heating a substrate and charging it with water vapour, comprising
An annealing chamber (15) with an adjustable and controllable supply of water into said chamber; and
Means for evacuating said chamber to a predefined pressure level; and
Heating means allowing for elevating the temperature of a substrate (16) arranged in said chamber.

2. The annealing apparatus according to claim 1, wherein the adjustable and controllable supply of water comprises a supply tank (11), a piping (12) between said supply tank (11) and the annealing chamber (15) with a control valve (14) allowing for defining the amount of water passing said valve.

3. The annealing apparatus according to claim 2, further comprising an actuator to control the valve (14) via respective electronics and software in a process control environment.

4. The annealing apparatus according to claim 1, further comprising a substrate holding means (17) to support said substrate (16).

5. The annealing apparatus according to claim 2, further comprising a blocking valve (13) to block a water flow between reservoir (10) and annealing chamber (15).

6. The annealing apparatus according to claim 1, wherein the heating means comprise quartz lamps.

7. The annealing apparatus according to claim 1, further comprising means for temperature and pressure control in annealing chamber (15).

8. The annealing apparatus according to claim 1, wherein said apparatus is integrated as a process chamber into a multi chamber processing tool in which an anti-fingerprint coating station is arranged adjacent to said annealing apparatus under vacuum conditions.

9. The annealing apparatus according to claim 8, wherein said multi chamber processing tool further comprises at least one processing station allowing for SiO₂ deposition and one process station for plasma cleaning.

10. A deposition process for an anti-fingerprint coating on a substrate, comprising a process sequence with the steps
(a) deposition of an anti-fingerprint coating on said substrate and
(b) curing said substrate in-situ in water vapour
without breaking vacuum between steps (a) and (b).

11. A deposition process according to claim 10, wherein said curing step (b) comprises exposing the surface of said substrate to an atmosphere of water vapour between 1×10⁻³ to 1×10⁻² mbar (hPa), at a temperature of 130° C. +/−10%.

12. A deposition process according to claim 11, wherein the water vapour pressure is 1×10⁻³ mbar (hPa).

13. A deposition process according to claim 10, wherein the temperature is being kept at 130° C. +/−5%.

14. A deposition process according to claim 10, wherein the performance time for said curing step is 5 s.

15. A deposition process according to claim 10, wherein the substrate after step (b) is subjected to an ex-situ curing step of 30 min at 130° C. under low relative humidity.

16. A deposition process according to claim 10, performed in a multi chamber tool in which an anti-fingerprint coating station is arranged adjacent to an annealing apparatus under vacuum conditions, wherein the annealing apparatus comprises
an annealing chamber with an adjustable and controllable supply of water into said chamber; and
means for evacuating said chamber to a predefined pressure level; and
heating means allowing for elevating the temperature of a substrate arranged in said chamber.
